(19) United States
(12) Patent Application Publication
(10) Pub. No.: US 2024/0328713 A1
(43) Pub. Date: Oct. 3, 2024

(54) DRYING APPARATUS, DRY CONDITION CONFIRMATION METHOD, AND WAFER STORAGE CONTAINER CLEANING APPARATUS

(71) Applicant: SHIBAURA MECHATRONICS CORPORATION, Kanagawa (JP)

(72) Inventors: Yukinobu NISHIBE, Kanagawa (JP); Toshihiro HAYASHI, Kanagawa (JP); Hisaaki MIYASAKO, Kanagawa (JP); Junji ISHIHARA, Kanagawa (JP); Hirokazu MASUDA, Kanagawa (JP)

(21) Appl. No.: 18/612,598

(22) Filed: Mar. 21, 2024

(30) Foreign Application Priority Data
Mar. 27, 2023 (JP) 2023-049623

(51) Int. Cl. F26B 21/10; F26B 25/22

(52) U.S. Cl. CPC F26B 21/10; F26B 25/22

(57) ABSTRACT

According to one embodiment of the present disclosure, a drying apparatus includes a drying chamber that holds a drying processing target in an inside thereof, a decompression device that decompresses the inside of the drying chamber; and a controller that controls the decompression device to decompress the inside of the drying chamber, thereby executing a drying processing of evaporating and removing moisture from the drying processing target. The controller executes, after the drying processing, an additional decompression processing of lowering a pressure of the inside of the drying chamber below a pressure at a time of the drying processing, for a predetermined time and determines a dry condition of the drying processing target based on a pressure of the inside of the drying chamber that has been reached after the additional decompression processing.

### CROSS-REFERENCE TO RELATED APPLICATIONS

This application is based on and claims priority from Japanese Patent Application No. 2023-049623 filed on Mar. 27, 2023 with the Japan Patent Office, the disclosure of which is incorporated herein in its entirety by reference.

### TECHNICAL FIELD

Embodiments of the present disclosure relate to a drying apparatus, a dry condition confirmation method, and a wafer storage container cleaning apparatus.

### BACKGROUND

In the manufacture of semiconductor wafers, wafer storage containers such as front opening unified pods (FOUP) or front opening shipping boxes (FOSB) have been used to store (accommodate) semiconductor wafers. Since the inside of the wafer storage containers may be contaminated when storing semiconductor wafers therein, the wafer storage containers are regularly cleaned. For example, as an apparatus for cleaning wafer storage containers, there is known an apparatus which has a cleaning chamber and a drying chamber. An ultrasonic cleaning and a high-pressure shower cleaning are alternately and repeatedly performed several times in the cleaning chamber and then, a hot air heating and a decompression drying are repeatedly performed several times in the drying chamber (see, e.g., Japanese Patent Laid-Open Publication No. 2002-126678).

### SUMMARY

As described above, wafer storage containers are regularly cleaned. However, when semiconductor wafers are stored in the wafer storage containers which are insufficiently dried after the cleaning, the semiconductor wafers may be contaminated, thereby causing product defects. Therefore, it is important to sufficiently dry the wafer storage container. However, the drying processing described above is executed under preset conditions, and a dry condition is not confirmed. Therefore, even if the drying of the wafer storage container is insufficient, it may not be noticed. Additionally, it is conceivable to lengthen the drying time in order to sufficiently dry the wafer storage container, but the drying processing takes a longer time than necessary and is not efficient.

The present disclosure provides a drying apparatus and a dry condition confirmation method capable of confirming a dry condition of a target such as a wafer storage container.

A drying apparatus according to an aspect of the present disclosure includes a drying chamber that holds a drying processing target in an inside thereof; a decompression device that decompresses the inside of the drying chamber; and a controller that controls the decompression device to decompress the inside of the drying chamber, thereby executing a drying processing of evaporating and removing moisture from the drying processing target. The controller, after the drying processing, executes an additional decompression processing of lowering a pressure of the inside of the drying chamber below a pressure at a time of the drying processing, for a predetermined time, and determines a dry condition of the drying processing target based on a pressure of the inside of the drying chamber that has been reached after the additional decompression processing.

According to an aspect of the present disclosure, it is possible to confirm a dry condition of a target.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating an example of a schematic configuration of a wafer storage container cleaning apparatus according to a first embodiment.

FIG. 2 is a side perspective view of an inside of a vacuum chamber according to the first embodiment.

FIG. 3 is a diagram for explaining an example of processing by a control unit according to the first embodiment.

FIG. 4 is a diagram for explaining pressure ranges according to the first embodiment.

FIG. 5 is a flowchart illustrating processing procedures by the control unit according to the first embodiment.

### DESCRIPTION OF EMBODIMENTS

In the following detailed description, reference is made to the accompanying drawings, which form a part of the present disclosure. The illustrative embodiments described in the detailed description, drawings, and claims are not meant to be limiting. Other embodiments may be utilized, and other changes may be made without departing from the spirit or scope of the subject matter presented herein.

Hereinafter, with reference to the accompanying drawings, embodiments of a drying apparatus, a dry condition confirmation method, and a wafer storage container cleaning apparatus disclosed in the present disclosure will be described in detail. In addition, the drying apparatus, the dry condition confirmation method, and the wafer storage container cleaning apparatus disclosed in the present disclosure are not limited to the following embodiments. Also, each embodiment and each modified example may be appropriately combined as long as no contradiction occurs. Additionally, in the following embodiments, as the drying apparatus, a drying apparatus used for a wafer storage container cleaning apparatus will be described as an example.

### First Embodiment

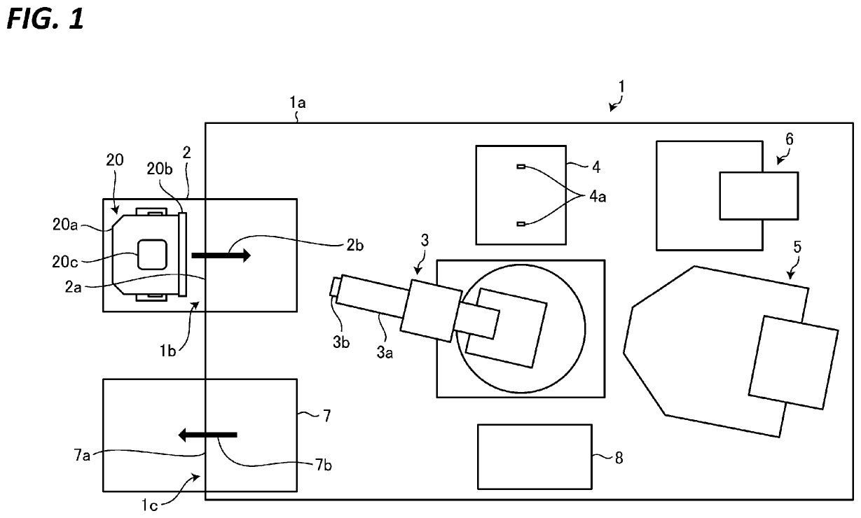

FIG. 1 is a plan view illustrating an example of a schematic configuration of a wafer storage container cleaning apparatus 1 according to the first embodiment. The wafer storage container cleaning apparatus 1 is provided, for example, in a factory that manufactures semiconductor wafers, and cleans wafer storage containers. As illustrated in FIG. 1, the wafer storage container cleaning apparatus 1 includes a load port 2, a robot 3, a disassembly/connection stage 4, a cleaning chamber 5, a vacuum chamber 6, an unload port 7, and a control unit 8. In addition, the vacuum chamber 6 is an example of a drying apparatus and is an example of a drying chamber. In addition, the control unit 8 is an example of a controller.

The robot 3, the disassembly/connection stage 4, the cleaning chamber 5, the vacuum chamber 6, and the control unit 8 are installed inside a casing (case) 1a of the wafer storage container cleaning apparatus 1. Meanwhile, the load port 2 and the unload port 7 are installed inside and outside the casing 1a of the wafer storage container cleaning apparatus 1.

The load port 2 carries a wafer storage container 20, which is disposed outside the casing 1a in the load port 2, into an inside of the casing 1a. The wafer storage container 20 is, for example, a front opening unified pod (FOUP) or front opening shipping box (FOSB) and includes a container body 20a and a door 20b. The container body 20a has an opening and a storage space for storing semiconductor wafers. The storage space is located inward from the opening and is in communication with the opening. The door 20b may be disassembled/connected with the container body 20a and is installed on the opening when connected with the container body 20a. The container body 20a is provided with a flange 20c. The flange 20c is a portion of the wafer storage container 20 that is grasped (held) by an overhead hoist transfer (OHT) or the robot 3.

For example, in the outside of the casing 1a of the load port 2, the wafer storage container 20 transported in a state where the flange 20c is grasped by the OHT is disposed. For example, as illustrated in FIG. 1, the wafer storage container 20 is disposed in the load port 2 such that the opening to which the door 20b is connected faces the casing 1a. When the wafer storage container 20 is disposed in the load port 2 in this manner, a shutter 2a installed on the opening 1b of the casing 1a is raised. Accordingly, the wafer storage container 20 may be carried into the inside of the casing 1a through the opening 1b. That is, the wafer storage container 20 may be carried into the inside of the wafer storage container cleaning apparatus 1. Then, the wafer storage container 20 is slid by a slide device of the load port 2 in a direction of an arrow 2b. Accordingly, the wafer storage container 20 is carried into the inside of the casing 1a.

The sliding by the sliding device will be described. For example, a pin provided in the sliding device is inserted into a hole formed in a bottom (placement surface) of the wafer storage container 20, so that the wafer storage container 20 is fixed to the sliding device. In this state, when the sliding device is slid in the direction of the arrow 2b, the wafer storage container 20 is also slide according to the movement of the pin. In this manner, the wafer storage container 20 is disposed on a predetermined portion of the load port 2 inside the casing 1a. When the wafer storage container 20 is thus carried into the inside of the casing 1a, the shutter 2a is lowered to close the opening 1b of the casing 1a. The sliding device, together with the pin, is lowered to a position lower than a bottom of the shutter 2a (the placement surface of the wafer storage container 20) and returns to its original position outside the casing 1a.

The robot 3 transfers the wafer storage container 20 to each part while grasping the flange 20c of the wafer storage container 20. The robot 3 includes a robot arm 3a and a robot hand 3b. The robot 3 stretches or rotationally moves the robot arm 3a while grasping the flange 20c by the robot hand 3b to thereby transfer the wafer storage container 20 to each part.

The disassembly/connection stage 4 disassembles the wafer storage container 20 into the container body 20a and the door 20b, or connects the container body 20a and the door 20b. On the disassembly/connection stage 4, latch keys 4a are provided. By rotating the latch keys 4a in a state of being inserted into keyholes formed in the door 20bof the wafer storage container 20, the wafer storage container 20 is disassembled (separated) into the container body 20a and the door 20b, or the container body 20a and the door 20b are connected to each other. For example, in the disassembly/connection stage 4, the wafer storage container 20 that is carried into the inside of the casing 1a is transferred by the robot 3. In this case, the disassembly/connection stage 4 disassembles the wafer storage container 20 into the container body 20a and the door 20b. Further, disassembling may be referred to as unlocking, and connecting may be referred to as locking.

The cleaning chamber 5 is a chamber for cleaning the wafer storage container 20. For example, in the cleaning chamber 5, the container body 20a, and the door 20b are separately transferred by the robot 3. The cleaning chamber 5 executes cleaning on the wafer storage container 20 while holding the container body 20a and the door 20b separately. For example, the cleaning chamber 5 is configured to have a cleaning chamber body having an opening in an upper surface thereof, and a cover portion capable of opening and closing the opening of the cleaning chamber body. The cleaning chamber 5 holds the door 20b on the cover portion of the cleaning chamber 5 and holds the container body 20a on the cleaning chamber body of the cleaning chamber 5. Here, the cleaning chamber 5 ejects a cleaning liquid (e.g., deionized water) to the container body 20a and the door 20b through a cleaning liquid nozzle while rotating the container body 20a and the door 20b by a rotating mechanism (not illustrated), and executes cleaning of the container body 20a and the door 20b. In addition, it is preferable to dispose the opening of the container body 20a to face downward in an inside of the cleaning chamber 5 in consideration of discharge properties of the cleaning liquid.

When the cleaning of the wafer storage container 20 is completed in the cleaning chamber 5, the container body 20a and the door 20b continue to be rotated in the cleaning chamber 5 and are dried therein by spraying dry air. Here, the drying in the cleaning chamber 5 is a treatment (temporary drying) that roughly dries the cleaning liquid that is attached to the wafer storage container 20. When the temporary-drying of the wafer storage container 20 is completed in the cleaning chamber 5, the robot 3 transfers the container body 20a and the door 20b in the cleaning chamber 5 separately to the vacuum chamber 6.

The vacuum chamber 6 is a chamber for vacuum-drying (main drying) of the wafer storage container 20. For example, the vacuum chamber 6 includes a holding unit for holding the container body 20a and the door 20b that are transferred to an inside thereof, a heater, and a decompression device capable of evacuating the inside of the vacuum chamber 6. The wafer storage container cleaning apparatus 1 according to this embodiment may be configured to include the vacuum chamber 6 and the control unit 8 to confirm a dry condition of the wafer storage container 20 vacuum-dried by the vacuum chamber 6. However, details thereof will be described later.

When the vacuum-drying of the wafer storage container 20 in the vacuum chamber 6 is completed, the robot 3 transfers the container body 20a and the door 20b in the vacuum chamber 6 to the disassembly/connection stage 4 separately. Then, the disassembly/connection stage 4 connects the container body 20a and the door 20b.

The unload port 7 carries the wafer storage container 20 (which has been cleaned and vacuum-dried) that is disposed in a portion of the unload port 7 inside of the casing 1a by the robot 3, to the outside of the casing 1a.

For example, in a portion of the unload port 7 inside the casing 1a, after the vacuum-drying, the wafer storage container 20 with the container body 20a and the door 20b that are connected in the disassembly/connection stage 4 is transferred by the robot 3 and disposed therein. When the wafer storage container 20 is disposed in the unload port 7, a shutter 7a installed on the opening 1c of the casing 1a is raised. Accordingly, the wafer storage container 20 may be carried out to the outside of the casing 1a from the opening 1c. That is, the wafer storage container 20 may be carried out to the outside of the wafer storage container cleaning apparatus 1. Then, the wafer storage container 20 is slid in a direction of an arrow 7b by a sliding device of the unload port 7 (which has the same mechanism as the sliding device of the load port 2), so that the wafer storage container 20 is carried out to the outside of the casing 1a. When the wafer storage container 20 is carried out to the outside of the casing 1a in this manner, the shutter 7a is lowered to close the opening 1c of the casing 1a.

The control unit 8 controls an overall operation of the wafer storage container cleaning apparatus 1. For example, the control unit 8 controls the load port 2, the robot 3, the disassembly/connection stage 4, the cleaning chamber 5, the vacuum chamber 6, and the unload port 7 to operate the load port 2, the robot 3, the disassembly/connection stage 4, the cleaning chamber 5, the vacuum chamber 6, and the unload port 7, as described above.

For example, the control unit 8 has a communication interface with a central processing unit (CPU), a read only memory (ROM), a random access memory (RAM), and a hard disk drive (HDD). They are connected via an internal bus.

The CPU executes various processes by using a memory area of the RAM as a temporary storage area for data used in various processes. The ROM and HDD store programs for executing various processes and various databases or tables used for executing various processes.

The communication interface is an interface for communicating with each of the above-described parts of the wafer storage container cleaning apparatus 1 and for communicating with external devices connected to the wafer storage container cleaning apparatus 1 via a network. For example, the communication interface is a network interface card.

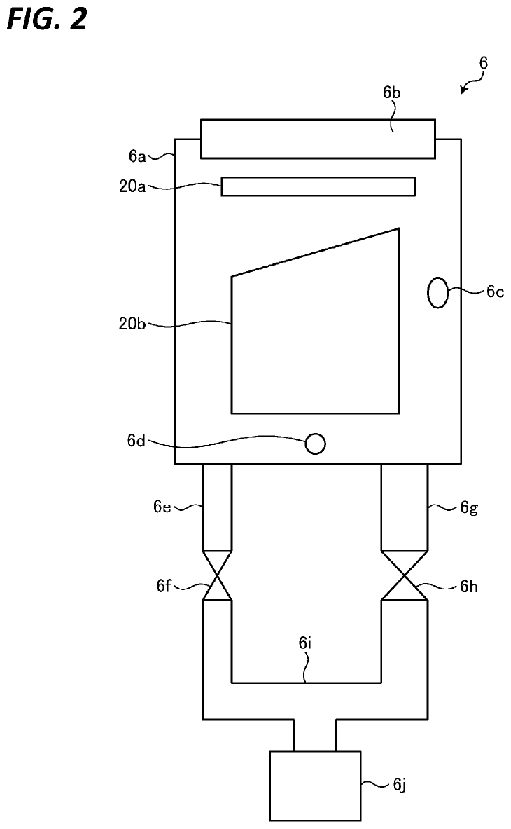

Next, a processing by the vacuum chamber 6 and the control unit 8 will be described. FIG. 2 is a side perspective view of an inside of a vacuum chamber according to the first embodiment. FIG. 2 is a schematic view of the vacuum chamber 6, illustrating a state where an opening in a vacuum chamber body 6a is closed by an opening and closing cover 6b.

As illustrated in FIG. 2, the vacuum chamber 6 includes the vacuum chamber body 6a, the opening and closing cover 6b, a heater 6c, and a pressure sensor 6d, and holds a drying processing target (a target to be subjected to drying processing) (e.g., the wafer storage container 20) in the inside thereof. In addition, the vacuum chamber 6 includes a first pipe 6e, a first valve 6f, a second pipe 6g, a second valve 6h, a pipe 6i, and a decompression device 6j with respect to the vacuum chamber body 6a.

The vacuum chamber body 6a has an opening in a top portion thereof and has a drying space in which the container body 20a is disposed. Specifically, an inner space of the vacuum chamber body 6a is an area including the opening and the drying space. The opening and closing cover 6b is installed on the top portion of the vacuum chamber body 6a. Specifically, the opening and closing cover 6b is installed to be openable and closable with respect to the opening of the vacuum chamber body 6a. The opening and closing cover 6b opens and closes the opening of the vacuum chamber body 6a by, for example, operating an air cylinder.

The inside (drying space) of the vacuum chamber body 6a is located inward of the opening and is in communication with the opening. The container body 20a and the door 20b are carried into the drying space from the opening by the robot 3 in a state where the opening and closing cover 6d is opened with respect to the opening. The heater 6c, under control of the control unit 8, emits heat to heat (raise the temperature of) the inside of the vacuum chamber body 6a. The pressure sensor 6d measures the pressure of the inside of the vacuum chamber body 6a. Furthermore, the arrangement of the container body 20a and the door 20b inside the vacuum chamber body 6a is not limited to the illustrated arrangement, and any arrangement may be possible. Also, the number of heaters 6c is not limited to that illustrated, and two or more heaters 6c may be installed. Also, positions of the heaters 6c and the pressure sensor 6d are not limited to those illustrated, and they may be installed at any position.

The vacuum chamber body 6a is provided with two exhaust ports for evacuating the drying space, and the first pipe 6e and the second pipe 6g are connected to each of the exhaust ports. The first pipe 6e is connected to the pipe 6i via a first valve 6f, and the second pipe 6g is connected to the pipe 6i via a second valve 6h. The pipe 6i is connected to the decompression device 6j. Here, the first pipe 6e has a low conductance compared to the second pipe 6g. For example, the first pipe 6e may have an orifice installed in the pipe, thereby adjusting the conductance.

The decompression device 6j decompresses the inside of the vacuum chamber 6. Specifically, the decompression device 6j decompresses the inside of the vacuum chamber body 6a by discharging gases inside the vacuum chamber body 6a to the outside. For example, the decompression device 6j is a dry pump, a mechanical booster pump, or a rotary pump. In addition, by introducing gases into the inside of the vacuum chamber 6 from a gas introduction port (not illustrated), the pressure of the inside of the vacuum chamber 6 may be returned to a pressure equivalent to atmospheric pressure.

In the vacuum chamber 6 according to this embodiment, a drying processing for drying the wafer storage container 20 by vacuum-drying, and an additional decompression processing for determining a dry condition of the wafer storage container 20 are executed. Specifically, the control unit 8 controls the decompression device 6j to decompress the inside of the vacuum chamber 6, thereby executing the drying processing of evaporating and removing moisture. Further, the control unit 8 executes, after the drying processing, the additional decompression processing of lowering the pressure of the inside of the vacuum chamber 6 below a pressure at the time of the drying processing for a predetermined time, and determines a dry condition of the target based on a pressure of the inside of the vacuum chamber 6 that has been reached after the predetermined time has lapsed.

### Drying Processing

The control unit 8 controls the robot to carry the container body 20a and the door 20b into the inside of the vacuum chamber body 6a and controls the heater 6c, the first valve 6f, the second valve 6h, and the decompression device 6j to execute the drying processing, in a state where the opening of the vacuum chamber body 6a is closed by the opening and closing cover 6b. Specifically, the control unit 8 operates the decompression device 6j while opening the first valve 6f and closing the second valve 6h, thereby executing the drying processing of the container body 20a and the door 20b. That is, the control unit 8 executes vacuum-drying of the container body 20a and the door 20b by heating the inside of the vacuum chamber 6 with the heater 6c while evacuating the inside of the vacuum chamber 6 by the decompression device 6j via the first pipe 6e, the first valve 6f, and the pipe 6i.

Here, the pressure of the inside of the vacuum chamber body 6a during the drying processing is reduced to be, for example, less than 2000 Pa. The pressure of less than 2000 Pa may be, for example, a pressure which is lower than 2000 Pa by several Pa to several hundred Pa. As the pressure of the inside of the vacuum chamber body 6a is reduced to be less than 2,000 Pa, water droplets attached to the container body 20a or the door 20b begin to evaporate at a temperature of 20° C. or higher. However, when the pressure of the inside of the vacuum chamber body 6a is reduced, the temperature at which the water droplets begin to evaporate is also lowered. Further, when the water droplets evaporate, the heat of the water droplets themselves is taken away by the heat of vaporization. Thus, when the pressure of the inside of the vacuum chamber body 6a is excessively lowered, the water droplets are frozen, thereby resulting in insufficient drying. Therefore, the pressure of the inside of the vacuum chamber body 6a during the drying processing is set to be within a pressure range where the water droplets do not freeze. In other words, the conductance in the first pipe 6e is adjusted such that the pressure of the inside of the vacuum chamber body 6a when evacuated by the decompression device 6j is within the pressure range where the water droplets do not freeze.

In addition, the heater 6c heats the wafer storage container 20 (the container body 20a and the door 20b) to a temperature (e.g., 30° C. to 100° C.) in which the wafer storage container 20 is not damaged. By the heating with the heater 6c, the temperature of the water droplets may be prevented from falling below 0° C.

### Additional Decompression Processing

The control unit 8 executes the additional decompression processing after executing the drying processing described above for a preset time. The additional decompression processing is executed by controlling the first valve 6f, the second valve 6h, and the decompression device 6j while the opening of the vacuum chamber body 6a is closed by the opening and closing cover 6b. Specifically, the control unit 8 executes the additional decompression processing on the inside of the vacuum chamber body 6a by actuating the decompression device 6j while closing the first valve 6f and opening the second valve 6h. That is, the control unit 8 evacuates the inside of the vacuum chamber body 6a by the decompression device 6j via the second pipe 6g, the second valve 6h, and the pipe 6i, thereby executing the additional decompression processing of the inside of the vacuum chamber body 6a.

Here, the second pipe 6g has a large conductance compared to the first pipe 6e. Therefore, a flow rate of gases discharged by the decompression device 6j during the additional decompression processing increases, and the pressure of the inside of the vacuum chamber body 6a during the additional decompression processing is lowered below the pressure at the time of the drying processing.

The control unit 8 executes the above-mentioned additional decompression processing for a predetermined time. The processing time for executing the additional decompression processing may be arbitrarily set based on a pre-confirmed processing time, but may also be set according to a type (a manufacturer or form) of the wafer storage container 20 which is the drying processing target. In this case, corresponding information (first corresponding information) where, for example, the type of the wafer storage container 20 and the processing time of the additional decompression processing correspond to each other, is stored in the HDD of the control unit 8. The CPU of the control unit 8 acquires the processing time according to the type of the wafer storage container 20 which is the drying processing target, from the first corresponding information stored in the HDD, and executes the additional decompression processing.

The type of the wafer storage container 20 which is the drying processing target may be determined, for example, based on identification information attached to the wafer storage container 20. Here, the identification information includes at least information about the type (the manufacturer or form) of the wafer storage container 20. When the wafer storage container 20 is carried into the inside of the casing 1a in the load port 2, the control unit 8 reads the identification information attached to the wafer storage container 20 to acquire the type of the wafer storage container 20 which is the drying processing target. The identification information may be, for example, a radio frequency identification (RFID) tag, a bar code, and a QR code (registered trademark).

### Dry Condition Determination Processing

The control unit 8 determines the dry condition of the wafer storage container 20 (the container body 20a and the door 20b) after executing the additional decompression processing described above. Specifically, the control unit 8 determines that the dry condition of the target (the wafer storage container 20) is sufficient when a pressure of the inside of the vacuum chamber 6 that has been reached after the additional decompression processing reaches a predetermined threshold value. Furthermore, the control unit 8 determines that the dry condition of the target is insufficient when the pressure of the inside of the vacuum chamber 6 that has been reached after the additional decompression processing does not reach the predetermined threshold value.

When the drying processing is executed by vacuum-drying, water droplets on a surface of the target (the wafer storage container 20) are evaporated and dried. However, in this case, since water molecules are evaporated to become gases, it is difficult to decompress below a certain pressure. Meanwhile, when sufficient drying is executed so that there is no moisture, since there is no evaporation of water molecules, it is possible to perform decompression to a pressure that reaches an exhaust capacity of the decompression device 6j.

Therefore, the control unit 8 acquires the pressure measured by the pressure sensor 6d and compares the pressure that has been reached after the additional decompression processing with a preset reference pressure (the predetermined threshold value) to determine the dry condition of the wafer storage container 20. Here, the reference pressure is set based on a relationship between a pre-confirmed dry condition and the reached pressure. For example, the reference pressure is set based on the pressure reached when the additional decompression processing is executed on the wafer storage container 20 in a dry condition. In one example, the reference pressure is set to about 10 Pa.

Furthermore, the reference pressure may be set based on the type (manufacturer or form) of the wafer storage container 20. A material or shape of the wafer storage container 20 (a surface area of the entire wafer storage container 20) may be different depending on the manufacturer and form. When a material or shape of the wafer storage container 20 is different, since the amount of outgassing during the additional decompression processing changes, the reached pressure changes. Therefore, the control unit 8 determines the type of the target (the wafer storage container 20) and determines the dry condition of the target (the wafer storage container 20) using the predetermined threshold value (reference pressure) that has been set according to the type of the target (the wafer storage container 20). In this case, for example, corresponding information (second corresponding information) where the type of the wafer storage container 20 and the reference pressure correspond to each other is stored in the HDD of the control unit 8. From the second corresponding information stored in the HDD, the CPU of the control unit 8 acquires the reference pressure according to the type of the wafer storage container 20 which is the drying processing target, and determines the dry condition of the wafer storage container 20 (the container body 20a and door 20b) based on the acquired reference pressure. Further, the type of the wafer storage container 20 is determined by the identification information of the wafer storage container 20 described above.

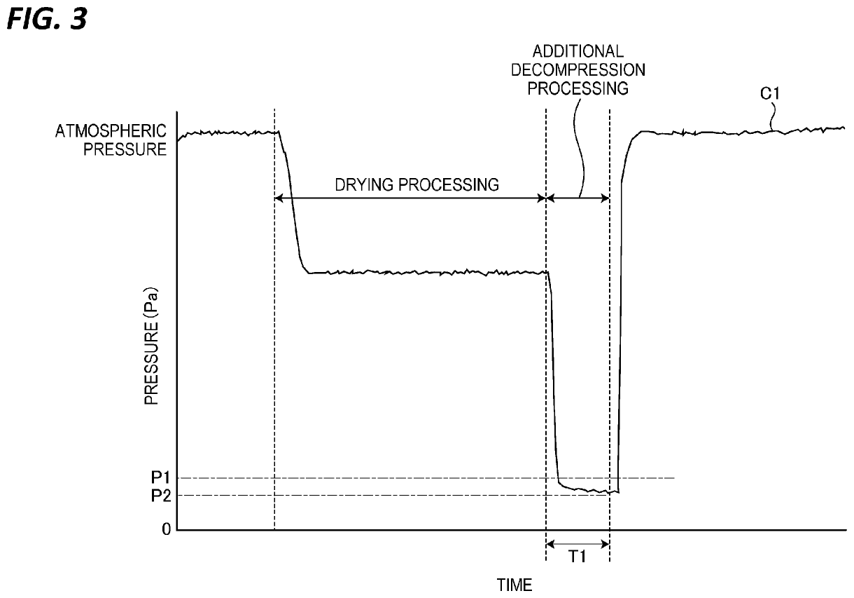

Hereinafter, an example of a dry condition determination processing by the control unit 8 will be described with reference to FIG. 3. FIG. 3 is a diagram for explaining an example of the dry condition determination processing by the control unit 8 according to the first embodiment. FIG. 3 illustrates a graph (curve C1) of the pressure in the inside of the vacuum chamber 6 when the drying processing and the additional decompression processing are executed, with a longitudinal axis representing pressure Pa and a transverse axis representing time. For example, as illustrated in the curve C1 of FIG. 3, the pressure of the inside of the vacuum chamber 6 is reduced by the drying processing and then further reduced by the additional decompression processing. The control unit 8 determines the dry condition of the wafer storage container 20 (the container body 20a and door 20b) based on the pressure of the inside of the vacuum chamber 6 after the additional decompression processing. Further, a processing time of the drying processing and the additional decompression processing combined is about 5 to 7 minutes.

For example, in FIG. 3, since pressure P2 after executing the additional decompression processing for a predetermined time T1 is below reference pressure P1, the control unit 8 determines that the dry condition of the wafer storage container 20 (the container body 20a and door 20b) is sufficient. When it is determined that that the drying processing is sufficient, the control unit 8 terminates drying of the wafer storage container 20 (the container body 20a and door 20b) by the vacuum chamber 6.

Meanwhile, when the pressure P2 exceeds the reference pressure P1, the control unit 8 determines that the dry condition of the wafer storage container 20 (the container body 20a and door 20b) is insufficient, and executes an additional drying processing on the wafer storage container 20 (the container body 20a and door 20b).

### Additional Drying Processing

As described above, when it is determined that the dry condition of the wafer storage container 20 (the container body 20a and door 20b) is insufficient, the control unit 8 executes an additional drying processing. For example, the control unit 8 performs control to execute the same drying processing as the first drying processing again. In this case, after the additional decompression processing, the control unit 8 operates the decompression device 6j and executes heating by the heater 6c while opening the first valve 6f and closing the second valve 6h in a state where the opening of the vacuum chamber body 6a is closed by the opening and closing cover 6b, thereby executing the drying processing. In this case, the control unit 8 executes the drying processing at the same temperature and for the same time as those of the first drying processing. In addition, when the pressure of the inside of the vacuum chamber 6 is returned to the pressure at the time of the first drying processing, it may be returned by introducing gases from the gas introduction port (not illustrated).

Alternatively, when it is determined that the drying condition is insufficient, the control unit 8 performs control to execute a drying processing under the same pressure and heating conditions as those of the first drying processing, and for a shorter time than that of the first drying processing. In this case, the control unit 8 operates, after the additional decompression processing, the decompression device 6j and executes heating by the heater 6c while opening the first valve 6f and closing the second valve 6h in a state where the opening of the vacuum chamber body 6a is closed by the opening and closing cover 6b, thereby executing the drying processing. Here, the control unit 8 executes the drying processing for a shorter time than the processing time of the first drying processing.

Alternatively, when it is determined that the drying condition is insufficient, the control unit 8 may execute a drying processing that continues the additional decompression processing until the reference pressure is reached. That is, the control unit 8 performs control to execute a drying processing that evaporates water droplets by the additional decompression processing. In this case, the control unit 8 continues the control in the additional decompression processing, thereby executing the drying processing. In this case, the control unit 8 may also execute heating by the heater 6c.

Here, processing contents of the above-mentioned additional drying processing may be set by selecting one of the above three cases in advance, but may also be changed according to a pressure state after the additional decompression processing. That is, the processing contents of the drying processing may be changed according to a degree of pressure after the additional decompression processing. In this case, a plurality of threshold values is set for the pressure of the inside of the vacuum chamber 6, so that a plurality of different pressure ranges is set. The control unit 8 changes a processing after the additional decompression processing according to the pressure range that has been reached by the pressure of the inside of the vacuum chamber 6 after the additional decompression processing.

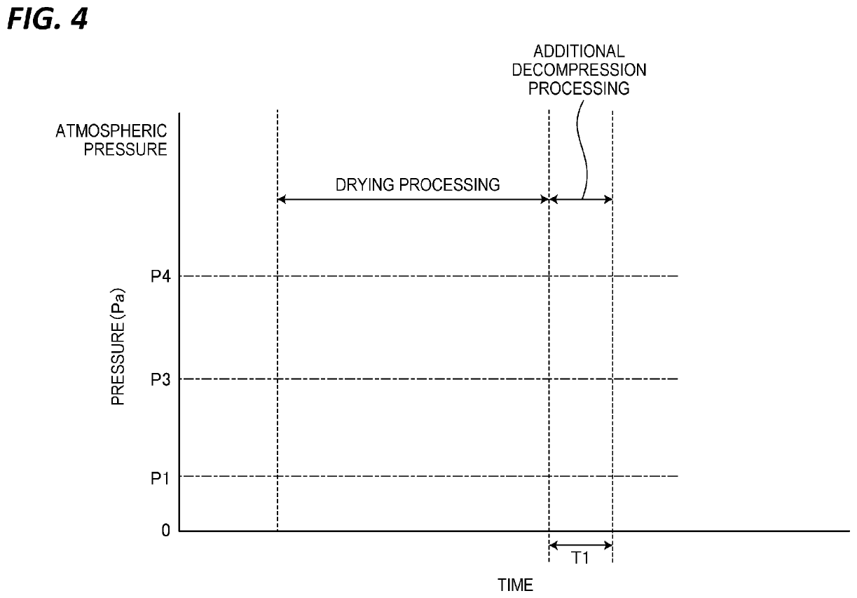

FIG. 4 is a diagram for explaining pressure ranges according to the first embodiment. FIG. 4 illustrates a graph with a longitudinal axis representing pressure Pa and a transverse axis representing time. For example, as illustrated in FIG. 4, in addition to the reference pressure P1, reference pressure P3 and reference pressure P4 are set for the pressure of the inside of the vacuum chamber 6. In this case, pressure ranges “P1-P3” and “P3-P4” are set as the pressure ranges. The control unit 8 changes the processing contents according to the pressure range where the pressure after the additional decompression processing is included.

For example, when the pressure after the additional decompression processing is included in the pressure range “P3-P4,” the control unit 8 performs control to execute either of the following A or B. A: a drying processing is executed under the same pressure and heating conditions as those of the first drying processing and with a shortened drying processing time. B: the same drying processing as the first drying processing is executed. In the case of the pressure range “P3-P4,” since there is a significant difference between the pressure and the reference pressure, it is more efficient to execute the same processing as the first drying processing. In addition, when a degree of pressure drop is low in the additional decompression processing, there is a possibility that water droplets are frozen, so that it is necessary to melt the water droplets. Therefore, when the pressure after the additional decompression processing is included in the pressure range “P3-P4,” the control unit 8 performs control to execute the drying processing equivalent to the first drying processing, again.

Also, for example, when the pressure after the additional decompression processing is included in the pressure range “P1-P3,” the control unit 8 executes a drying processing that continues the additional decompression processing until the pressure after the additional decompression processing reaches the reference pressure. In the case of the pressure range “P1-P3,” since there is a small difference between the pressure and the reference pressure, it is more efficient to continue the additional decompression processing. Therefore, when the pressure after the additional decompression processing is included in the pressure range “P1-P3,” the control unit 8 performs control to, for example, execute heating by the heater 6c while continuing the additional decompression processing.

In addition, in FIG. 4, a case where two pressure ranges are set is explained as an example, but the embodiment is not limited thereto, and a case where three or more pressure ranges are set may also be used.

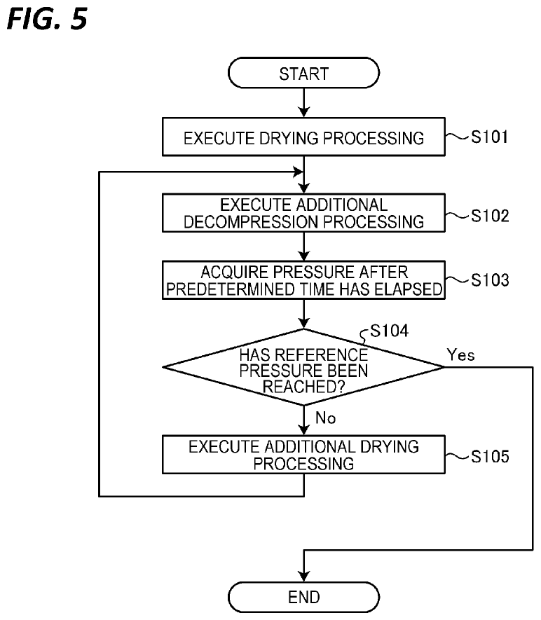

Next, processing procedures by the control unit 8 of the wafer storage container cleaning apparatus 1 will be described with reference to FIG. 5. FIG. 5 is a flowchart illustrating the processing procedures by the control unit 8 according to the first embodiment. In FIG. 5, a processing after the container body 20a and the door 20b are carried into the vacuum chamber body 6a and the opening of the vacuum chamber body 6a is closed by the opening/closing cover 6b is illustrated.

For example, as illustrated in FIG. 5, the control unit 8 controls the heater 6c, the first valve 6f, the second valve 6h, and the decompression device 6j to execute a drying processing for a preset time (step S101).

Continuously, the control unit 8 controls the first valve 6f, the second valve 6h, and the decompression device 6j in a state where the opening and closing cover 6b is closed, to execute an additional decompression processing for a predetermined time (step S102).

Continuously, the control unit 8 acquires the pressure after the predetermined time has elapsed (after the additional decompression processing) (step S103) and determines whether the pressure has reached the reference pressure (step S104). Here, when the pressure after the additional decompression processing has reached the reference pressure (step S104, Yes), the control unit 8 terminates a processing for drying the wafer storage container 20 (the container body 20a and door 20b).

Meanwhile, in step S104, when the pressure after the additional decompression processing has not reached the reference pressure (step S104, No), the control unit 8 executes an additional drying processing (step S105), thereby executing the processing after step S102 again. Furthermore, when the additional drying processing is a processing that continues the additional decompression processing, the control unit 8 acquires the pressure during the processing over time, and terminates the processing for drying the wafer storage container 20 (the container body 20a and door 20b) at a time when the acquired pressure reaches the reference pressure.

According to the first embodiment, after the drying processing, the control unit 8 executes an additional decompression processing of lowering the pressure of the inside of the vacuum chamber 6 below the pressure at the time of the drying processing, and determines the dry condition of the wafer storage container 20 based on the pressure of the inside of the vacuum chamber 6 that has been reached after the additional decompression processing. Thus, the wafer storage container cleaning apparatus 1 may determine the dry condition of the target based on the reached pressure, which varies depending on whether water molecules are evaporated or not, and may confirm the dry condition of the wafer storage container 20. As a result, the wafer storage container cleaning apparatus 1 may eliminate the use of a wafer storage container in an insufficient drying condition and suppress the occurrence of defects in semiconductor wafers that are caused by contamination from the wafer storage container. Furthermore, since the wafer storage container cleaning apparatus 1 may determine the dry condition of the wafer storage container 20, it is possible to dry the wafer storage container 20 efficiently by avoiding spending more time than necessary for drying processing.

Further, according to the first embodiment, when the pressure of the inside of the vacuum chamber 6 that has been reached after the additional decompression processing reaches the reference pressure, the control unit 8 determines that the dry condition of the wafer storage container 20 is sufficient. Further, when the pressure of the inside of the vacuum chamber 6 that has been reached after the additional decompression processing does not reach the reference pressure, the control unit 8 determines that the dry condition of the wafer storage container 20 is insufficient and executes the additional drying processing on the wafer storage container 20. Thus, the wafer storage container cleaning apparatus 1 may reliably dry the wafer storage container 20.

Furthermore, according to the first embodiment, a plurality of threshold values is set for the pressure of the inside of the vacuum chamber 6, so that a plurality of different pressure ranges is set. The control unit 8 changes a processing after the additional decompression processing according to the pressure range that has been reached by the pressure of the inside of the vacuum chamber 6 after the additional decompression processing. Thus, the wafer storage container cleaning apparatus 1 can execute an additional drying processing according to a degree of drying of the wafer storage container 20, and may execute the additional drying processing efficiently.

Furthermore, according to the first embodiment, the control unit 8 determines a type of the wafer storage container 20 and determines a dry condition of the wafer storage container 20 using reference pressure that has been set according to the type of the wafer storage container 20. Thus, the wafer storage container cleaning apparatus 1 may determine the dry condition of the wafer storage container 20 using reference pressure that has been set according to a material or shape of the wafer storage container 20, and may appropriately determine the dry condition of various wafer storage containers 20.

### Other Embodiments

In the first embodiment described above, the first pipe 6e having a relatively small conductance and the second pipe 6g having a relatively large conductance are connected to the vacuum chamber body 6a. Further, a case in which a drying processing is executed through the first pipe 6e and an additional decompression processing is executed through the second pipe 6g has been described. However, the embodiment is not limited thereto. For example, one pipe may be connected to the vacuum chamber body 6a, and the drying processing and the additional decompression processing may be executed through the pipe.

In this case, for example, the one pipe may have a conductance equivalent to that of the second pipe 6g, and the drying processing and the additional decompression processing may be executed through the one pipe. In order to regulate the pressure during the drying processing, the vacuum chamber 6 is connected to a gas supply so that dry gases are supplied to the inside of the vacuum chamber 6. That is, the control unit 8 controls the decompression device 6j to decompress the inside of the vacuum chamber body 6a during the drying processing, while controlling the gas supply to supply dry gases to the inside of the vacuum chamber body 6a, thereby preventing the pressure of the inside of the vacuum chamber body 6a from being excessively low.

In the additional decompression processing, the control unit 8 stops the supply of dry gases by the gas supply to decompress the inside of the vacuum chamber body 6a.

In this manner, by using dry gases during the drying processing, the drying processing and the additional decompression processing may be executed with one pipe. In addition, by using dry gases during the drying process, it is possible to form an airflow in which evaporated water molecules are discharged by the dry gases, thereby improving drying efficiency.

Furthermore, in the first embodiment described above, descriptions were made for a case where the wafer storage container 20 is a drying processing target (target to be subjected to drying processing). However, the embodiment is not limited thereto, and in addition to the wafer storage container 20, an object whose drying processing is executed by vacuum-drying may be a target. In other words, a drying condition confirmation method according to the present disclosure may be applied, in addition to the wafer storage container cleaning apparatus.

Furthermore, in the first embodiment described above, after the drying processing, the control unit 8 executes the additional decompression processing of lowering the pressure of the inside of the vacuum chamber 6 below the pressure at the time of the drying processing. In addition, descriptions were made on a case where the dry condition of the wafer storage container 20 is determined based on the pressure of the inside of the vacuum chamber 6 that has been reached after the additional decompression processing. However, the embodiment is not limited thereto. For example, the control unit 8 may, after the additional decompression processing, decompress the pressure of the inside of the vacuum chamber 6 to a predetermined pressure lower than the pressure at the time of the drying process, and then stop the decompressing of the inside of the vacuum chamber 6. Then, the control unit 8 may determine the dry condition of the wafer storage container 20 by determining whether the pressure measured by the pressure sensor 6d rises after maintaining a state where the decompressing of the inside of the vacuum chamber 6 is stopped for a predetermined time. Furthermore, the predetermined pressure is a pressure higher than the reference pressure P1. The predetermined pressure is, for example, a pressure greater than 10 Pa and less than or equal to 50 Pa.

In the determination of the dry condition by the above determination method, the control unit 8 determines that the dry condition of the target (e.g., the wafer storage container 20) is insufficient when the pressure of the inside of the vacuum chamber 6 after the lapse of the predetermined time in the state where the decompressing of the inside of the vacuum chamber 6 is stopped, has risen from the predetermined pressure. For example, when water droplets remain in the wafer storage container 20, if the inside of the vacuum chamber 6 is maintained for a predetermined time at a predetermined pressure that is lower than the pressure at the time of the drying processing, the remaining water droplets evaporate and the pressure of the inside of the vacuum chamber 6 rises. Therefore, the control unit 8 determines that the dry condition of the target is insufficient when the pressure of the inside of the vacuum chamber 6 rises from the predetermined pressure. Meanwhile, when the pressure of the inside of the vacuum chamber 6 after the lapse of the predetermined time in the state where the decompressing of the inside of the vacuum chamber 6 is stopped, does not rise from the predetermined pressure, the control unit 8 determines that the dry condition of the target (e.g., the wafer storage container 20) is sufficient. For example, when no water droplets remain in the wafer storage container 20, even if the inside of the vacuum chamber 6 is maintained for a predetermined time at a predetermined pressure lower than the pressure at the time of the drying process, the water droplets do not evaporate and the pressure of the inside of the vacuum chamber 6 does not rise. Therefore, the control unit 8 determines that the drying condition of the target is sufficient, when the pressure of the inside of the vacuum chamber 6 does not rise from the predetermined pressure.

From the foregoing content, it will be appreciated that various embodiments of the present disclosure have been described herein for purposes of illustration, and that various modifications can be made without departing from the scope and spirit of the present disclosure. Accordingly, the various embodiments disclosed herein are not intended to be limiting, with the true scope and spirit being indicated by the following claims.

What is claimed is:

1. A drying apparatus comprising:
a drying chamber configured to hold a drying processing target in an inside thereof;
a decompressor configured to decompress the inside of the drying chamber; and
a controller configured to control the decompressor to decompress the inside of the drying chamber, thereby executing a drying processing of evaporating and removing moisture from the drying processing target,
wherein the controller executes, after the drying processing, an additional decompression processing of lowering a pressure of the inside of the drying chamber below a pressure at a time of the drying processing, for a predetermined time, and determines a dry condition of the drying processing target based on a pressure of the inside of the drying chamber that has been reached after the additional decompression processing.

2. The drying apparatus according to claim 1, wherein when the pressure of the inside of the drying chamber that has been reached after the additional decompression processing does not reach a predetermined threshold value, the controller determines that the dry condition of the drying processing target is insufficient, and executes an additional drying processing on the drying processing target.

3. The drying apparatus according to claim 1, wherein a plurality of threshold values is set for the pressure of the inside of the drying chamber, so that a plurality of different pressure ranges is set, and
wherein the controller changes a processing after the additional decompression processing according to a pressure range that has been reached by the pressure of the inside of the drying chamber after the additional decompression processing.

4. The drying apparatus according to claim 1, wherein the drying processing target is a wafer storage container including a front opening unified pod (FOUP) and a front opening shipping box (FOSB).

5. The drying apparatus according to claim 1, wherein when the pressure of the inside of the drying chamber that has been reached after the additional decompression processing reaches a predetermined threshold value, the controller determines that the drying condition of the drying processing target is sufficient.

6. The drying apparatus according to claim 2, wherein the controller determines a type of the drying processing target and determines the dry condition of the drying processing target using the predetermined threshold value that has been set according to the type of the drying processing target.

7. A drying condition confirmation method comprising:
decompressing an inside of a drying chamber that holds a drying processing target in the inside thereof, thereby executing a drying processing of evaporating and removing moisture from the drying processing target,
after the drying processing, executing, for a predetermined time, an additional decompression processing of lowering a pressure of an inside of the drying chamber below a pressure at a time of the drying processing, and determining a dry condition of the drying processing target based on a pressure of the inside of the drying chamber that has been reached after the additional decompression processing.

8. A drying apparatus comprising:
a drying chamber configured to hold a drying processing target in an inside thereof;
a decompressor configured to decompress the inside of the drying chamber; and
a controller configured to control the decompressor to decompress the inside of the drying chamber, thereby executing a drying processing of evaporating and removing moisture from the drying processing target,
wherein, after the drying processing, the controller reduces a pressure of the inside of the drying chamber to a predetermined pressure lower than a pressure at a time of the drying processing, and determines a dry condition of the drying processing target based on whether the pressure of the inside of the drying chamber after lapse of a predetermined time in a state where the decompressing of the inside of the drying chamber is stopped, rises from the predetermined pressure.

9. A drying condition confirmation method comprising:
controlling a drying chamber and a decompressor that decompresses an inside of the drying chamber where a drying processing target is held, thereby decompressing the inside of the drying chamber and executing a drying processing of evaporating and removing moisture from the drying processing target; and
after the drying processing, reducing a pressure of the inside of the drying chamber to a predetermined pressure lower than a pressure at a time of the drying processing, and determining a dry condition of the drying processing target based on whether the pressure of the inside of the drying chamber after lapse of a predetermined time in a state where the decompressing of the inside of the drying chamber is stopped, rises from the predetermined pressure.

10. A wafer storage container cleaning apparatus comprising:
a cleaning chamber configured to supply a cleaning liquid to a wafer storage container, thereby cleaning the wafer storage container, and
a drying apparatus configured to vacuum-dry the wafer storage container cleaned in the cleaning chamber,
wherein the drying apparatus is the drying apparatus according to claim 1.
